(19) United States
(12) Patent Application Publication
(10) Pub. No.: US 2006/0160301 A1
(43) Pub. Date: Jul. 20, 2006

(54) Method for fabricating a metal-insulator-metal capacitor

(76) Inventor: Joon Bum Shim, Seongnam-si (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(21) Appl. No.: 11/303,467

(22) Filed: Dec. 15, 2005

(30) Foreign Application Priority Data
Dec. 15, 2004 (KR) 10-2004-0106159

(51) Int. Cl. H01L 21/8242; H01L 29/94; H01L 21/20

(52) U.S. Cl. 438/253; 438/381; 257/300

(57) ABSTRACT

Disclosed are: (i) a method for fabricating a MIM capacitor in a semiconductor device, which can produce a MIM capacitor in fewer process steps; and (ii) a semiconductor device in which a MIM capacitor having a larger capacitance relative to conventional approaches is formed. The method comprises the steps of: (a) forming a capping layer, a bottom metal layer, a dielectric layer and a top metal layer above a semiconductor substrate in successive order; (b) forming a photoresist pattern on the top metal layer, the photoresist pattern masking a region to form the MIM capacitor; and (c) etching the top metal layer, the dielectric layer and the bottom metal layer in successive order using the photoresist pattern as a mask, thus forming the MIM capacitor including a top electrode, a dielectric insulator and a bottom electrode of which side walls are substantially collinear and have sidewalls that are substantially perpendicular to the capping layer.

### CROSS-REFERENCE TO RELATED APPLICATION

This application claims priority to and the benefit of Korean Patent Application No. 10-2004-0106159, filed in the Korean Intellectual Property Office on Dec. 15, 2004, the entire contents of which are incorporated herein by reference.

### BACKGROUND OF THE INVENTION

1. Field of the Invention

The present invention relates to a method for fabricating a capacitor in a semiconductor device, and more specifically, to a method for fabricating a capacitor having a Metal-Insulator-Metal (MIM) structure.

2. Description of the Related Art

Semiconductor devices, such as capacitors, may be used for various purposes. In general, to realize a higher operational speed of a capacitor, it is necessary to decrease the frequency-dependence by reducing the resistivity of capacitor electrodes. Also, for a large capacitance, it is generally advantageous to decrease a thickness of a dielectric insulator between capacitor electrodes, use a material having a high dielectric constant as a dielectric insulator, or increase an area of the capacitor electrodes.

According to a type of junction structure, capacitors formed in a semiconductor device can generally be classified as either a MOS structure, a PN junction structure, a polysilicon-insulator-polysilicon (PIP) structure, or a metal-insulator-metal (MIM) structure. Among these general types of capacitors, a capacitor having some structure other than a MIM structure generally includes single-crystalline or polycrystalline silicon as at least one of capacitor electrodes. However, single-crystalline or polycrystalline silicon has a limitation in facilitating a decrease of the resistivity of capacitor electrodes, due to the material properties thereof. A MIM capacitor with relatively low resistivity electrodes may therefore be used in applications that may benefit from a capacitor of a high operational speed.

FIG. 1 is cross-sectional view showing a conventional method of fabricating a MIM capacitor.

Referring to FIG. 1, an intermetal dielectric layer 110 is formed on a semiconductor substrate 100, and then a metal line 120 is formed on the intermetal dielectric layer 110. Next, a first capping layer 130 is formed on the metal line 120. To form a metal-insulator-metal (MIM) capacitor 140, a bottom metal layer (used to form bottom electrode 141), a dielectric layer (used to form capacitor insulator 142), and a top metal layer (used to form top electrode 143) are formed on the capping layer 130 in successive order. Also, a second capping layer (not shown), such as a silicon nitride layer, may be formed on the top metal layer 143. A photoresist pattern (not shown) is formed on the second capping layer using a conventional photolithography process. Then, the second capping layer and the top metal layer are patterned by an etch process using the photoresist pattern as an etch mask, thus forming a top electrode 143. Thereafter, the photoresist pattern is removed by an ashing process.

Next, another photoresist pattern (not shown) is formed by a photolithography process. Then, the dielectric layer and the bottom metal layer are etched using this second photoresist pattern as an etch mask, thus forming a dielectric insulator 142 and a bottom electrode 141. Thereafter, the second photoresist pattern is removed by an ashing process. As a result, a metal-insulator-metal (MIM) capacitor 140 in which the bottom electrode 141, the dielectric insulator 142, and the top electrode 143 are disposed in successive order, is formed.

However, in such a conventional method of fabricating a MIM capacitor, the process of photolithography, etching and ashing is generally performed two times successively. Therefore, the whole fabricating method becomes relatively complicated because of the repetitive process steps. In addition, because a dimension of the top electrode 143 is different from that of the bottom electrode 141, the capacitance of the MIM capacitor depends primarily on the dimension of the top electrode 143.

### SUMMARY OF THE INVENTION

It is an object of the present invention to provide a method for fabricating a MIM capacitor in a semiconductor that decreases the number of repetitive process steps, such as successive photolithographic, etch, and ashing processes.

Another object of the present invention is to provide a semiconductor device in which a MIM capacitor having a relatively large capacitance is formed.

In a first aspect, embodiments of the present invention may be directed to a method for fabricating a MIM capacitor in a semiconductor device, comprising the steps of: (a) forming a capping layer, a bottom metal layer, a dielectric layer and a top metal layer above a semiconductor substrate in successive order; (b) forming a photoresist pattern on the top metal layer, the photoresist pattern masking a region to form the MIM capacitor; and (c) etching the top metal layer, the dielectric layer and the bottom metal layer in successive order using the photoresist pattern as a mask, thus forming the MIM capacitor including a top electrode, a dielectric insulator and a bottom electrode of which side walls are substantially in line and substantially perpendicular to the capping layer. Here, the capping layer and the dielectric layer preferably comprise silicon nitride (Si₃N₄, but commonly termed “SiN”), the bottom metal layer preferably comprises a Ti/TiN bilayer, and the top metal layer preferably comprises TiN.

Preferably, the etching step comprises a dry-etch process using a decoupled plasma source. Here, the dry-etch process may be performed under conditions including a source power of from about 500 W to about 1000 W, a bias power of from about 400 W to about 600 W, a pressure of from about 50 mT to about 100 mT, and an electrostatic chuck temperature of from about 40° C. to about 60° C. In addition, the dry-etch process may include a plasma formed using CF₄ gas at a flow rate of from about 40 sccm to about 100 sccm, Cl₂ gas of from about 50 sccm to about 100 sccm, CHF₃ gas of from about 10 sccm to about 20 sccm, and O₂ gas of from about 5 sccm to about 10 sccm.

Also, the dry-etch process may be performed until a surface of the capping layer is detected by an end point detector. Here, the end point detector may operate using light having a wavelength of about 3485 nm and an initial dead time of not less than about 45 seconds. Furthermore, detecting the surface of the capping layer by the end point detector may occur when an increase of the reflected or refracted wavelength is detected at least five times in a window box of about 1×0.5 sizes.

In a second aspect, embodiments of the present invention may be directed to a semiconductor device provided with a MIM capacitor, the MIM capacitor comprising: (a) a capping layer, a bottom metal layer, a dielectric layer and a top metal layer above a semiconductor substrate in successive order; (b) forming a photoresist pattern on the top metal layer, the photoresist pattern masking a region to form the MIM capacitor; and (c) etching the top metal layer, the dielectric layer and the bottom metal layer in successive order using the photoresist pattern as a mask, thus forming the MIM capacitor including a top electrode, a dielectric insulator and a bottom electrode of which side walls are substantially in line and substantially perpendicular to the capping layer. Preferably, the capping layer and the dielectric layer are formed of SiN, the bottom metal layer is formed of Ti/TiN, and the top metal layer is formed of TiN.

These and other aspects of embodiments of the invention will become evident by reference to the following description of embodiments, often referring to the accompanying drawings.

### BRIEF DESCRIPTION OF DRAWINGS

FIG. 1 is cross-sectional view showing a conventional method of fabricating a MIM capacitor.

FIGS. 2 and 3 are cross-sectional views showing a method for fabricating a MIM capacitor in accordance with an embodiment of the present invention.

FIG. 4 is a cross-sectional view showing a first exemplary electrical connection to the bottom electrode of a MIM capacitor structure made in accordance with embodiments of the present invention.

FIG. 5 is a top view of the MIM capacitor structure of FIG. 4.

FIG. 6 is a cross-sectional view showing a second exemplary electrical connection to the bottom electrode of a MIM capacitor structure made in accordance with embodiments of the present invention.

### DETAILED DESCRIPTION OF EMBODIMENTS OF THE INVENTION

Hereinafter, preferred embodiments of the present invention will be described with reference to the accompanying drawings.

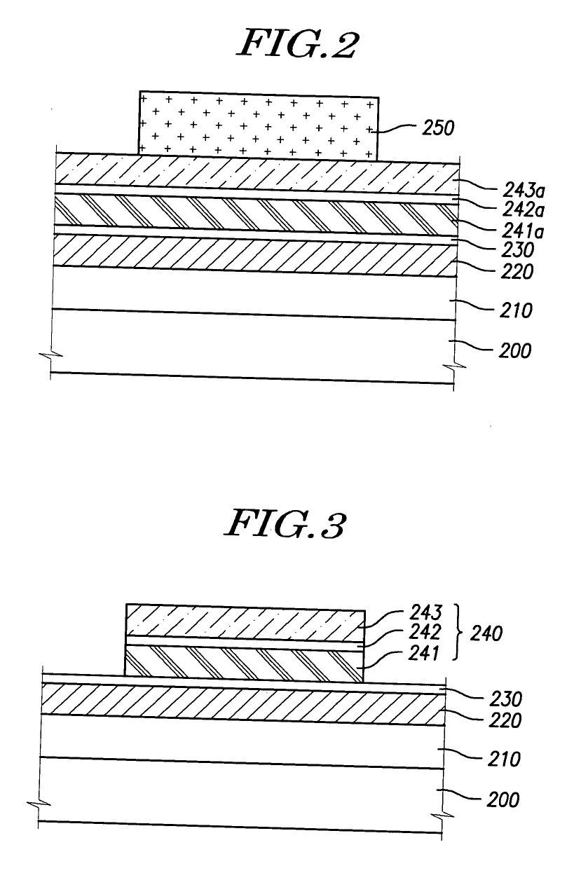

FIGS. 2 and 3 are cross-sectional views showing a method for fabricating a MIM capacitor in accordance with an embodiment of the present invention.

Referring to FIG. 2, an intermetal dielectric layer 210 is formed on a semiconductor substrate 200, such as a silicon substrate, and then a metal layer 220 is formed on the intermetal dielectric layer 210. Next, a capping layer 230, for example comprising silicon nitride (SiN), is formed on the metal layer 220. In order to form a metal-insulator-metal (MIM) capacitor 240 as shown in FIG. 3, a bottom metal layer 241a, a dielectric layer 242a, and a top metal layer 243a are formed on the capping layer (e.g., SiN) 230 in successive order. For example, the bottom metal layer 241a may comprise a Ti/TiN bilayer, the dielectric layer 242a may comprise silicon dioxide (SiO₂), silicon oxynitride (SiOₓN_{y}, but commonly referred to as SiON) or silicon nitride (Si₃N₄), and the top metal layer 243a may comprise TiN. The Ti/TiN bilayer may be made in accordance with conventional techniques (e.g., sputtering a layer of Ti metal having a thickness of, for example, from 100 to 1000 Å, then depositing a layer of TiN having a thickness of, for example, from 50 to 500 Å by conventional chemical vapor deposition (CVD) or by sputtering or physical vapor deposition (PVD) of Ti metal in a nitrogen-containing atmosphere (e.g., an atmosphere including N₂ gas or NH₃ gas). Alternatively, the Ti/TiN bilayer may be made by sputtering a layer of Ti metal having a thickness of, for example, from 150 to 1000 Å, then annealing at a temperature of, for example, from 600 to 850° C. in a nitrogen-containing atmosphere (e.g., comprising N₂ gas or NH₃ gas).

Next, a photoresist pattern 250 for use as a mask is formed on the top metal layer 243a. However, before forming the photoresist pattern 250, another (or a second) capping layer (e.g., comprising silicon nitride; not shown) may be formed on the top metal layer 243a. The photoresist pattern 250 defines a region in which a MIM capacitor 240 shown in FIG. 3 may be formed.

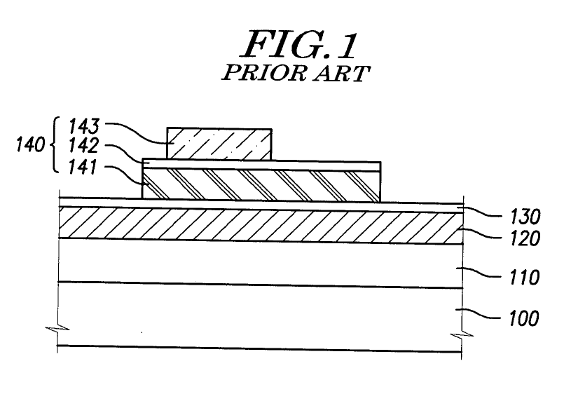

Referring to FIG. 3, an etch process is performed using the photoresist pattern 250 shown in FIG. 2 as an etch mask, thus removing the exposed portions of the top metal layer 243a, the dielectric layer 242a, and the bottom metal layer 241a in successive order. Therefore, a MIM capacitor 240 including a bottom electrode 241, a dielectric insulator 242, and a top electrode 243 is formed. Here, the side walls of the top electrode 243, the dielectric insulator 242, and the bottom electrode 241 are substantially collinear and substantially perpendicular to the upper surface of capping layer 230 so that the capacitance of the MIM capacitor 240 can be larger than that of the conventional MIM capacitor 140 shown in FIG. 1.

A dry-etch process is preferably used as the etch process. In particular, in order to form the sidewalls of the top electrode 243, the dielectric insulator 242, and the bottom electrode 241 to be substantially collinear and substantially perpendicular to capping layer 230, a decoupled plasma source (DPS) is preferably used. Here, the dry-etch process using the DPS is performed under conditions comprising a source power of from about 500 W to about 1000 W, a bias power of from about 400 W to about 600 W, a pressure of from about 50 mT to about 100 mT, and/or an electrostatic chuck temperature of from about 40° C. to about 60° C.

In such conditions, a polymer that may be formed along the side walls of the capacitor material layers during the etch process can be relatively easily removed, thus enabling the sidewalls of the top electrode 243, the dielectric insulator 242, and the bottom electrode 241 to be substantially collinear and substantially perpendicular to capping layer 230. Thus, the dry-etch process may preferably further comprise forming and/or using a plasma comprising CF₄ gas at a flow rate of from around 40 sccm to around 100 sccm, Cl₂ gas at a flow rate of from around 50 sccm to around 100 sccm, CHF₃ gas at a flow rate of from around 10 sccm to around 20 sccm, and O₂ gas at a flow rate of from around 5 sccm to around 10 sccm.

Meanwhile, the dry-etch process is performed until the capping layer (e.g., SiN) 230 on the metal layer or line 220 is exposed. An end point detector (EPD) may be used for such a purpose. The EPD is preferably operated under conditions including use of reflection or refraction light having a wavelength of about 3485 nm and an initial dead time not less than about 45 seconds. Under such conditions, even if both the dielectric layer 242a and the capping layer 230 comprise silicon nitride, the endpoint of the dry-etch process is detected not when the dielectric layer 242 is exposed, but when the capping layer 230 is exposed. To improve the reliability of the etch process, it is preferable to stop the etch process when an increase of the reflected or refracted wavelength is detected at least five times in a window box of 1×0.5 sizes. After the dry-etch process is finished, the photoresist pattern 250 is removed by an ashing process, for example.

According to embodiments of the present invention as described above, a photolithographic process, an etch process and an ashing process are performed only one time to form the MIM capacitor, thus enabling the number of repetitive or overall process steps to be decreased. In addition, because the top electrode has substantially the same dimensions as the bottom electrode, the capacitance of the MIM capacitor may be increased relative to the conventional approach of FIG. 1.

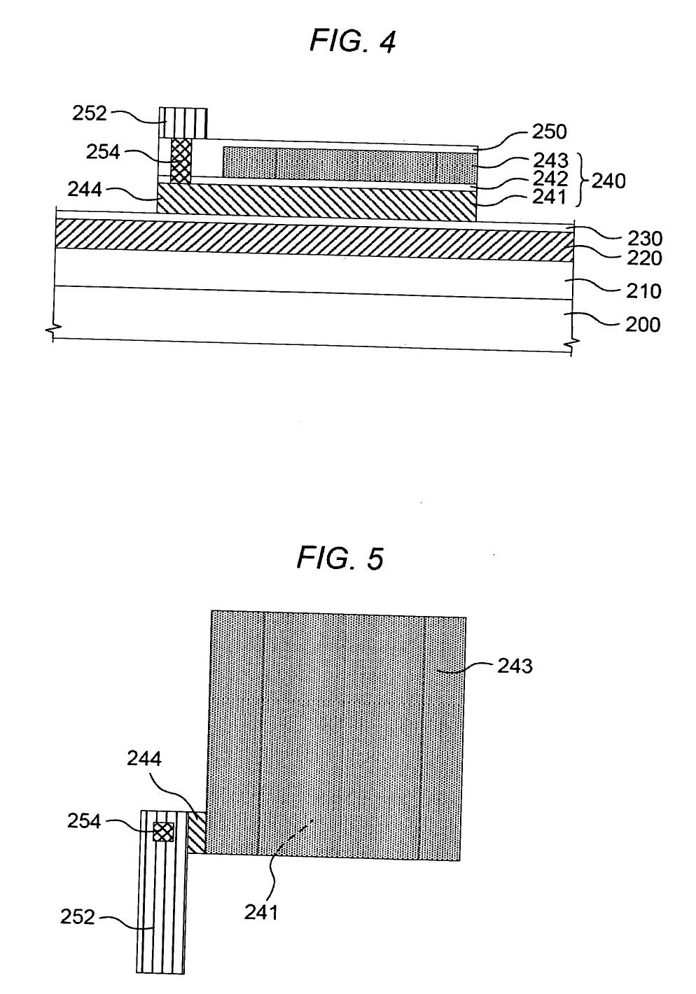

FIG. 4 shows a cross-sectional view of a first exemplary electrical connection to the bottom electrode of a MIM capacitor structure made in accordance with embodiments of the present invention. As discussed above with reference to FIGS. 2 and 3, an intermetal dielectric layer 210 may be formed on a semiconductor substrate 200, such as a silicon substrate. Then, metal layer 220 (which generally comprises one or more parallel wires or lines) may be formed on intermetal layer 210. Next, a capping layer (e.g., SiN) 230 may be formed on the metal layer 220. A MIM capacitor 240 can include first electrode 241, dielectric insulator 242, and second electrode 243. As discussed above, first electrode 241, dielectric insulator 242, and second electrode 243 may be substantially collinear and have side walls that are substantially perpendicular to capping layer 230.

In addition, an electrical connection to the bottom electrode (e.g., first electrode 241) of the MIM capacitor 240 may be formed by adding another dielectric insulator, a via, and another metal layer. Dielectric insulator 250 may be formed on second electrode 243 and dielectric insulator 242, then planarized in accordance with conventional insulator planarizing techniques. Via 254 may be formed through dielectric insulators 242 and 250 in accordance with conventional via or contact forming techniques. Metal layer 252 may be formed on dielectric insulator 250 in accordance with conventional deposition and photolithographic techniques, and may be electrically coupled to first electrode 241 by way of via 254. In this fashion, the bottom electrode (e.g., first electrode 241) can be electrically connected to outside circuits through metal layer 252. Further, first electrode 241, dielectric insulator 242, second electrode 243, and dielectric insulator 250 may be substantially collinear and have sidewalls that are substantially perpendicular to capping layer 230.

FIG. 5 shows a top view of the MIM capacitor structure of FIG. 4. First electrode 241 may have an extension or “landing pad” 244 to accommodate via 254 to complete a connection to metal layer 252, as discussed above. Also, such an extension (e.g., metal pad 244, alone or together with via 254 and/or metal layer 252) may be used to connect to other circuitry. Similarly, second electrode 243 may have a branch (not shown) to connect to other circuitry as well.

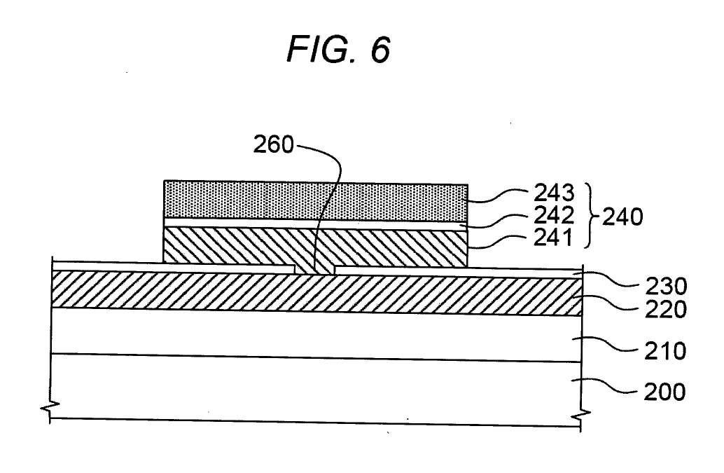

FIG. 6 shows a cross-sectional view of a second exemplary electrical connection to the bottom electrode of a MIM capacitor structure made in accordance with embodiments of the present invention. An intermetal dielectric layer 210 may be formed on a semiconductor substrate 200, such as a silicon substrate. Then, metal layer 220 (which generally comprises one or more parallel wires or lines) may be formed on intermetal layer 210. Next, a capping layer (e.g., SiN) 230 may be formed on the metal layer 220.

In order to accommodate a connection between the bottom capacitor electrode and other circuitry, a via hole can be formed in capping layer 230 and via 260 can be filled in the via hole at the same time that the first electrode 241 is formed. Alternatively, via 260 can be formed in capping layer 230 by the same process as via 254 in FIG. 5. A MIM capacitor 240 can include first electrode 241, dielectric insulator 242, and second electrode 243. As discussed above, first electrode 241, dielectric insulator 242, and second electrode 243 may be substantially collinear and have sidewalls that are substantially perpendicular to capping layer 230. First electrode 241 may connect to metal layer 220 to provide an electrical connection to the bottom electrode of MIM capacitor 240. By having the via (e.g., via 260) under the bottom capacitor electrode (e.g., first electrode 241), the overlap between capacitor electrodes per unit area can be maximized.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for fabricating a metal-insulator-metal (MIM) capacitor in a semiconductor device, the method comprising the steps of:
successively forming a capping layer, a bottom metal layer, a dielectric layer and a top metal layer above a semiconductor substrate;
forming a photoresist pattern on the top metal layer, the photoresist pattern defining a MIM capacitor region; and
etching the top metal layer, the dielectric layer and the bottom metal layer in successive order using the photoresist pattern as a mask, thus forming the MIM capacitor including a top electrode, a dielectric insulator and a bottom electrode of which side walls are substantially collinear and substantially perpendicular to the capping layer.

2. The method of claim 1, wherein the etching step comprises dry-etching with a decoupled plasma source (DPS).

3. The method of claim 2, wherein the dry-etching comprises conditions including a source power of from about 500 W to about 1000 W, a bias power of from about 400 W to about 600 W, a pressure of from about 50 mT to about 100 mT, and an electrostatic chuck temperature of from about 40° C. to about 60° C.

4. The method of claim 2, wherein the dry-etching comprises forming a plasma from CF₄ gas having a flow rate of from about 40 sccm to about 100 sccm, Cl₂ gas having a flow rate of from about 50 sccm to about 100 sccm, CHF₃ gas having a flow rate of from about 10 sccm to about 20 sccm, and O₂ gas having a flow rate of from about 5 sccm to about 10 sccm.

5. The method of claim 2, wherein the dry-etching further comprises detecting a surface of the capping layer with an end point detector.

6. The method of claim 5, wherein the end point detector operates using light having a wavelength of about 3485 nm and an initial dead time of not less than about 45 seconds.

7. The method of claim 6, wherein detecting the surface of the capping layer comprises detecting an increase of the wavelength at least five times in a window box of 1×0.5 sizes.

8. The method of claim 1, wherein the capping layer and the dielectric layer comprise silicon nitride, the bottom metal layer comprises a Ti/TiN bilayer, and the top metal layer comprises TiN.

9. A metal-insulator-metal (MIM) capacitor, comprising:
a capping layer;
a first metal layer;
a first dielectric layer; and
a second metal layer;
the first metal layer, the first dielectric layer, and the second metal layer having substantially collinear sidewalls that are substantially perpendicular to the capping layer.

10. The semiconductor device of claim 9, wherein the capping layer comprises silicon nitride.

11. The semiconductor device of claim 9, wherein the first dielectric layer comprises silicon nitride.

12. The semiconductor device of claim 10, wherein the first dielectric layer comprises silicon nitride.

13. The semiconductor device of claim 9, wherein the first metal layer comprises Ti and/or TiN.

14. The semiconductor device of claim 13, wherein the first metal layer comprises a Ti/TiN bilayer.

15. The semiconductor device of claim 9, wherein the second metal layer comprises TiN.

16. The semiconductor device of claim 9, wherein the first metal layer, the first dielectric layer, and the second metal layer have at least three sidewalls that are substantially collinear along substantially their entire lengths and at least a fourth sidewall that is substantially collinear along at least a substantial portion of its length.

17. The semiconductor device of claim 15, wherein the fourth sidewall is substantially collinear along substantially its entire length.

18. A method for fabricating a metal-insulator-metal (MIM) capacitor, comprising the steps of:
defining a MIM capacitor region comprising a bottom metal layer, a dielectric layer thereon, and a top metal layer thereon, the MIM capacitor region being on or above a capping layer; and
forming a MIM capacitor including a top electrode, a dielectric insulator and a bottom electrode having sidewalls that are substantially collinear and substantially perpendicular to the capping layer.

19. The method of claim 18, wherein the forming step comprises dry-etching the bottom metal layer, dielectric layer, and top metal layer with a decoupled plasma source (DPS).

20. The method of claim 18, wherein the dry-etching conditions include a source power of from about 500 W to about 1000 W, a bias power of from about 400 W to about 600 W, and an electrostatic chuck temperature of from about 40° C. to about 60° C.

21. The method of claim 18, wherein the dry-etching comprises forming a plasma from a fluorocarbon source at a flow rate of from about 40 sccm to about 100 sccm, a chlorine source at a flow rate of from about 50 sccm to about 100 sccm, a hydrofluorocarbon source at a flow rate of from about 10 sccm to about 20 sccm, and an oxygen source at a flow rate of from about 5 sccm to about 10 sccm.
